(19) United States
(12) Patent Application Publication
(10) Pub. No.: US 2026/0089935 A1
(43) Pub. Date: Mar. 26, 2026

(54) MEMORY DEVICE HAVING GLOBAL SILICON ON INSULATOR

(71) Applicant: Micron Technology, Inc., Boise, ID (US)

(72) Inventors: Mandar Suresh Bhoir, Boise, ID (US); Dan Mihai Mocuta, Boise, ID (US); Durai Vishak Nirmal Ramaswamy, Boise, ID (US)

(21) Appl. No.: 19/335,983

(22) Filed: Sep. 22, 2025

Related U.S. Application Data
(60) Provisional application No. 63/698,335, filed on Sep. 24, 2024.

(51) Int. Cl. H10B 12/00

(52) U.S. Cl. CPC H10B 12/50; H10B 12/09

(57) ABSTRACT

A variety of applications can include a memory device having a periphery to a memory array of the memory device, with the periphery having one or more devices constructed in a semiconductor on insulator in the periphery. The semiconductor on insulator can be silicon on insulator.

### PRIORITY APPLICATION

This application claims the benefit of priority to U.S. Provisional Application Ser. No. 63/698,335, filed Sep. 24, 2024, which is incorporated herein by reference in its entirety.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 represents a top view of an example memory device having a memory array region and a periphery to the memory array region, in accordance with various embodiments.

FIG. 2 is a representation of a cross-sectional view of an example structure of the memory device of FIG. 1, in accordance with various embodiments.

FIGS. 3-8 illustrate an example process flow for fabricating a memory device having a periphery to an array in which the periphery includes component devices of the memory device constructed in portions of a global semiconductor on insulator, in accordance with various embodiments.

FIGS. 9-14 illustrate an embodiment of another example process flow for fabricating a memory device having a periphery to an array in which the periphery includes component non-memory cell devices of the memory device constructed in portions of a global semiconductor on insulator, in accordance with various embodiments.

FIG. 15 shows a top view of a structure in an embodiment of an example periphery for forming component devices of periphery circuits or pitch circuits for a memory device, in accordance with various embodiments.

FIG. 16 is a representation of a cross-sectional view of an example structure in the periphery to a memory array of a memory device having a high-voltage transistor structured in a bulk silicon substrate, in accordance with various embodiments.

FIG. 17 is a representation of a cross-sectional view of an example structure in the periphery to a memory array of a memory device, with the periphery having a high-voltage transistor structured in semiconductor on insulator, in accordance with various embodiments.

FIG. 18 is a representation of a cross-sectional view of another example structure in the periphery to a memory array of a memory device, with the periphery having a high-voltage transistor structured in semiconductor on insulator, in accordance with various embodiments.

FIG. 19 is a flow diagram of features of an example method of forming a memory device, in accordance with various embodiments.

FIG. 20 is a flow diagram of features of another example method of forming a memory device, in accordance with various embodiments.

FIG. 21 is a schematic of an example dynamic random-access memory device that can include an architecture in which component devices in the periphery to the memory array of the dynamic random-access memory device are structured in semiconductor on insulator, in accordance with various embodiments.

FIG. 22 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

To meet speed, power, and area-efficiency specifications of advanced memory structures, complementary metal-oxide-semiconductor (CMOS) technologies for DRAM should satisfy a number of characteristics. The advanced memory structures can include, but are not limited to, double data rate 6 dynamic random-access memory (DDR6), low power double data rate 6 dynamic random-access memory (LP6), graphics double data rate 7 dynamic random-access memory (GDDR7), or high bandwidth memory (HBM). Characteristics should include use of logic technology similar to high-performance CMOS (HP-CMOS), extremely low leakage, scaled dimensions to follow access line (WL) and digit line (DL) pitch and to improve area-efficiency, lower device-to-device variability, and a low-cost solution. A high-performance CMOS device is a relatively high speed, low power device. For example, a high-performance CMOS device on semiconductor on insulator in a memory device periphery, as taught herein, can provide a 30% to 40% improvement in speed or power as compared to a CMOS on a bulk substrate in the memory device periphery.

Scaling of conventional bulk planar CMOS technologies has its own limitation. It is difficult to control device single error corrections (SECs), leakage, variability, and parasitic components beyond certain dimensions. Moreover, advanced logic-like CMOS technologies such as, but not limited to, a fin field-effect transistor (FinFET), silicon on insulator (SOI) CMOS (SOI-CMOS) using a SOI substrate, nanosheet field effect transistor (NSFET) appear to be beneficial devices for a periphery to a memory array, but implementations of such devices are challenging in terms of cost and co-integration with the memory array of the memory device.

In various embodiments, component devices within a memory device can be created on global semiconductor on insulator, such as global-SOI (G-SOI), selectively in a non-array region of the memory device, while the memory array remains on bulk substrate, such as a silicon (Si) substrate. The component devices can include HP-CMOS and other devices. Such G-SOI CMOS technology is capable of providing high performance similar to SOI logic technologies. G-SOI CMOS technology has better short-channel control, which can provide lower leakage for low-power options compared to conventional bulk substrate devices. Such technology provides lower device parasitic, for example, junction capacitance, and lower device variability. Such technology provides capability to have partially-depleted (PD) SOI technology option and a fully-depleted (FD) SOI technology option. Such technology allows co-integration of DRAM low-voltage CMOS devices and high-voltage CMOS devices. Such technology can include significantly enhanced body-biasing capability, for example ultra-thin body and buried oxide fully depleted SOI (UTBB-FD-SOI) MOS transistors. Such technology may provide area scalability well beyond bulk CMOS technologies. Such technology can also provide a low-cost solution.

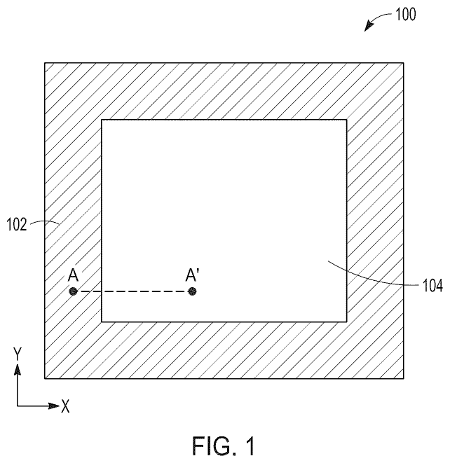

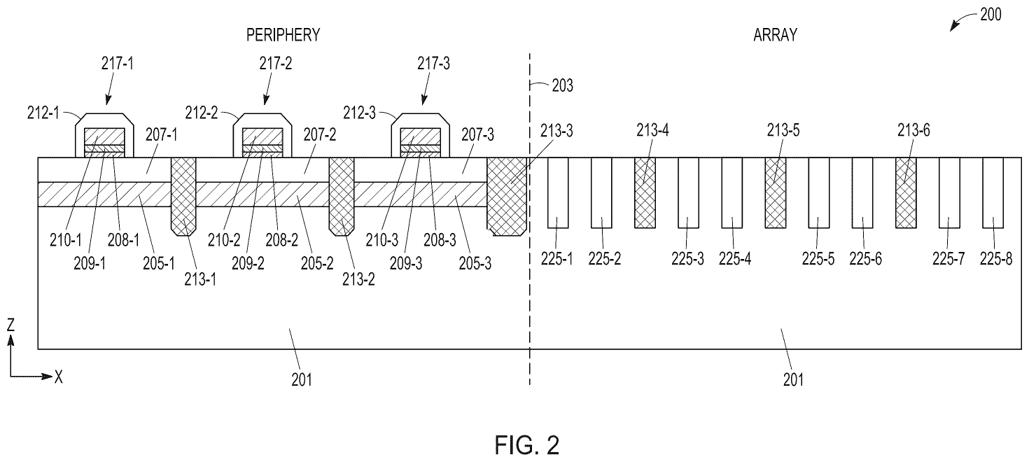

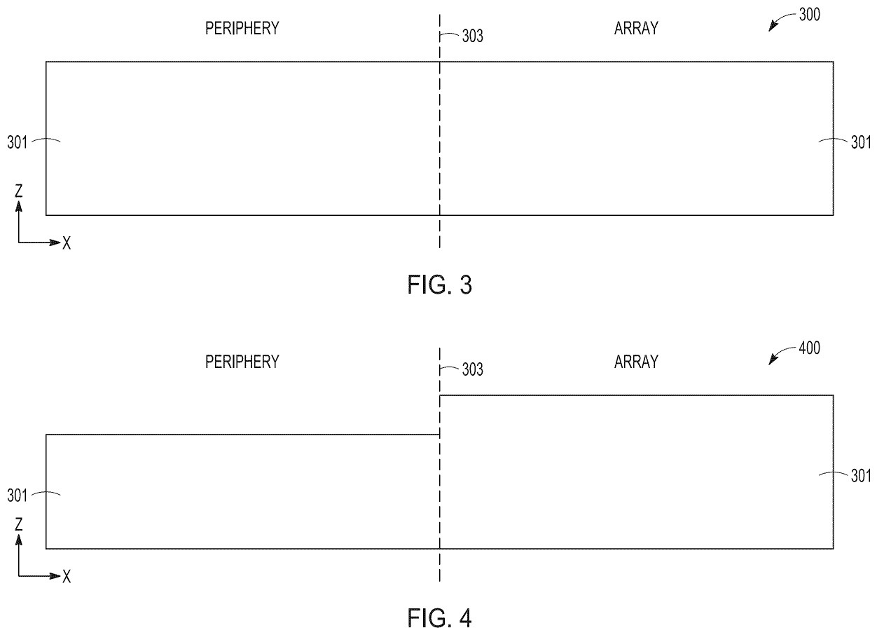

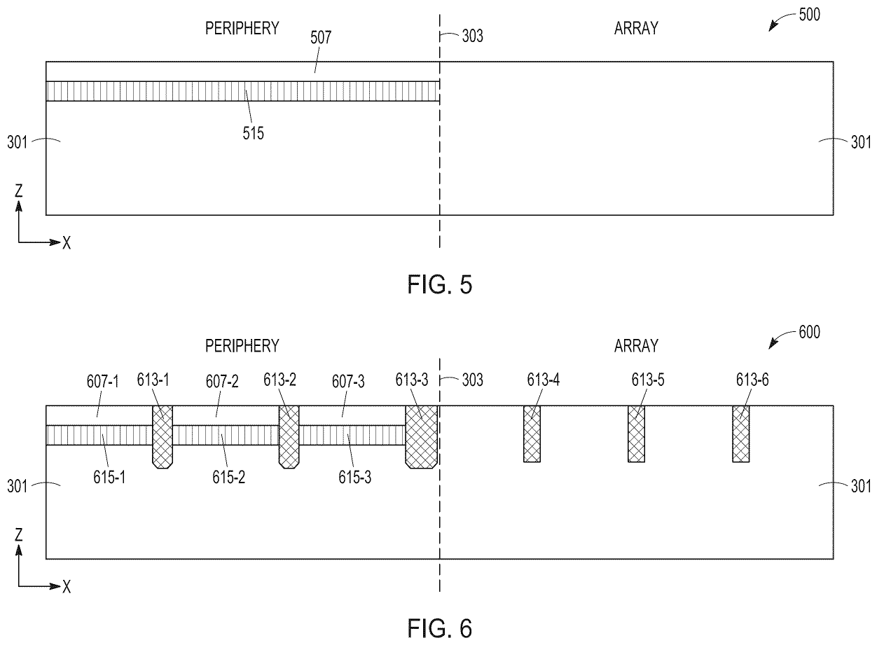

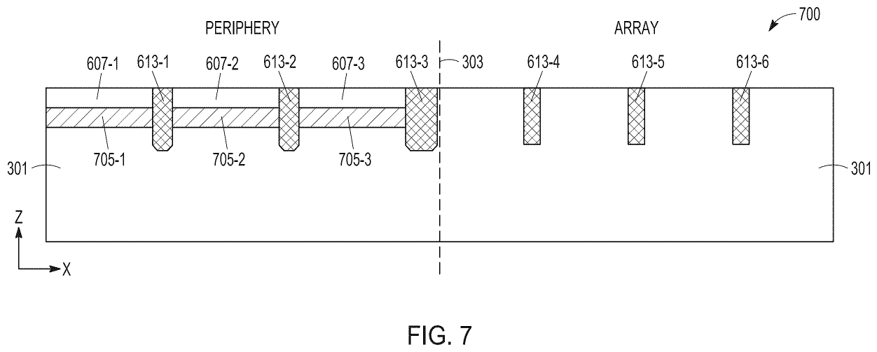

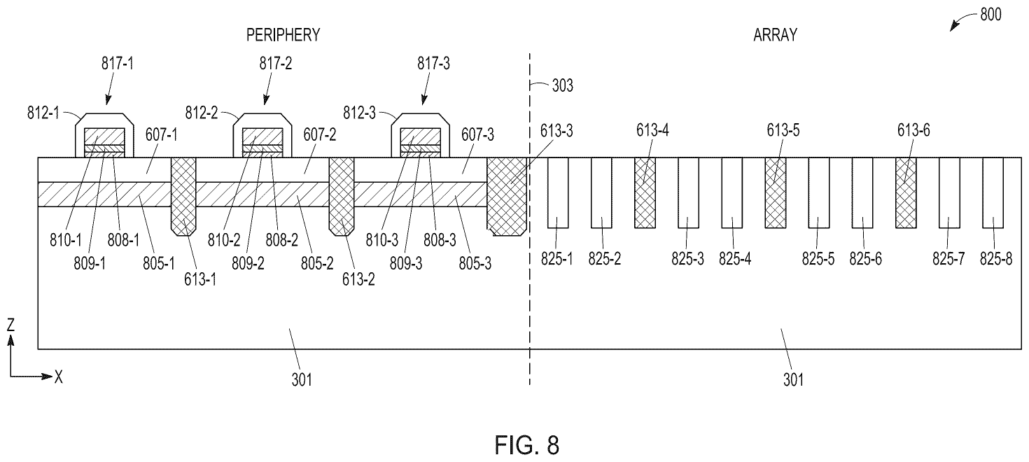

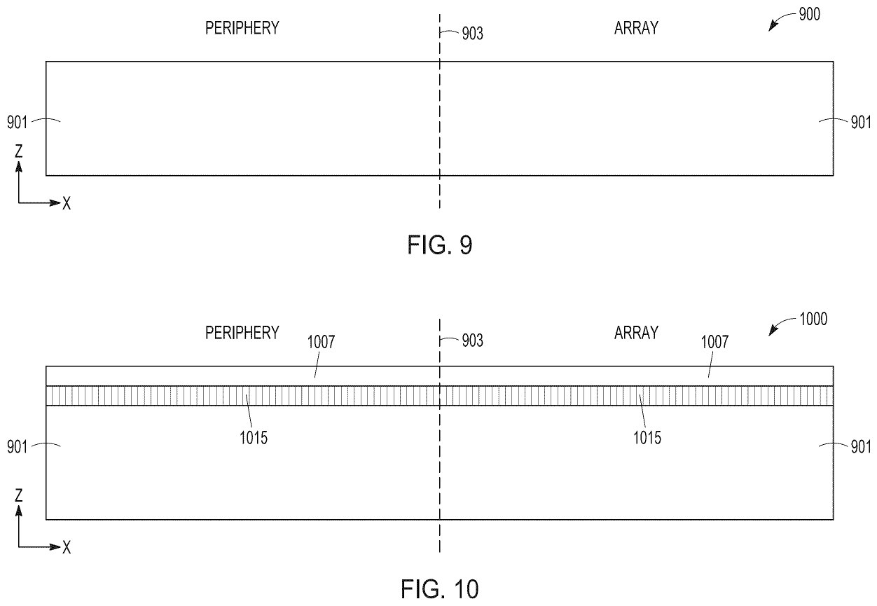

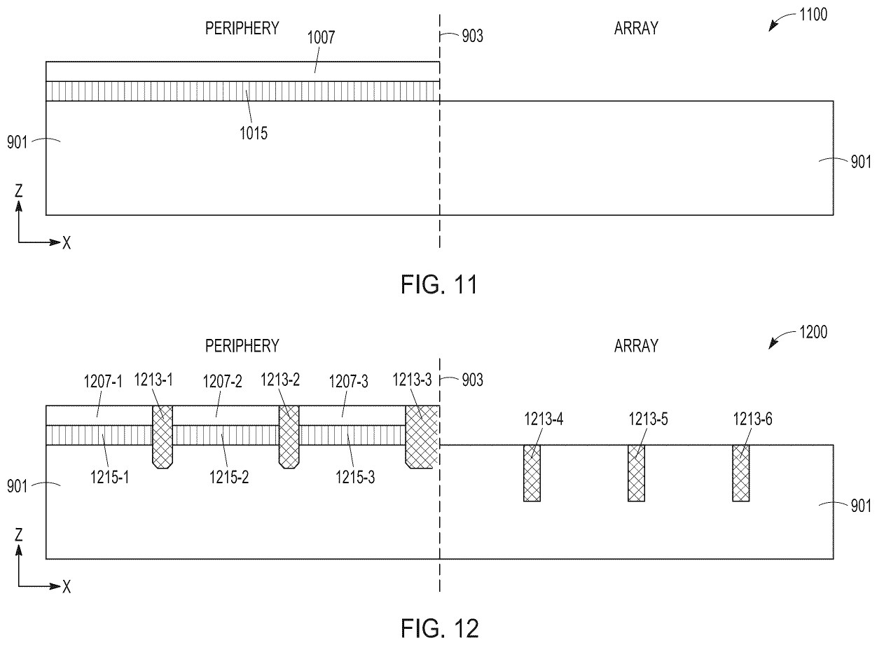

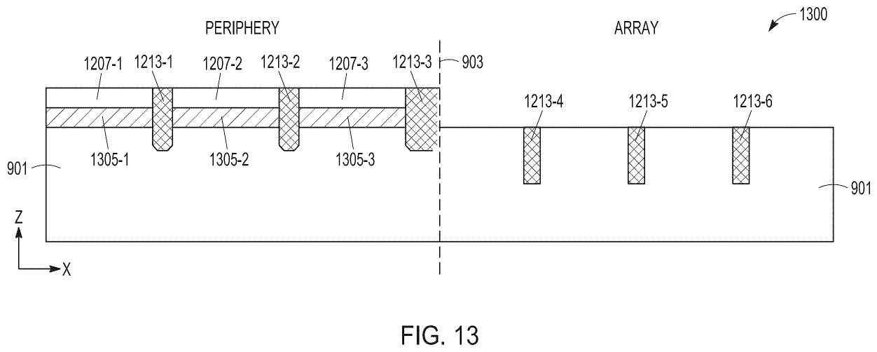

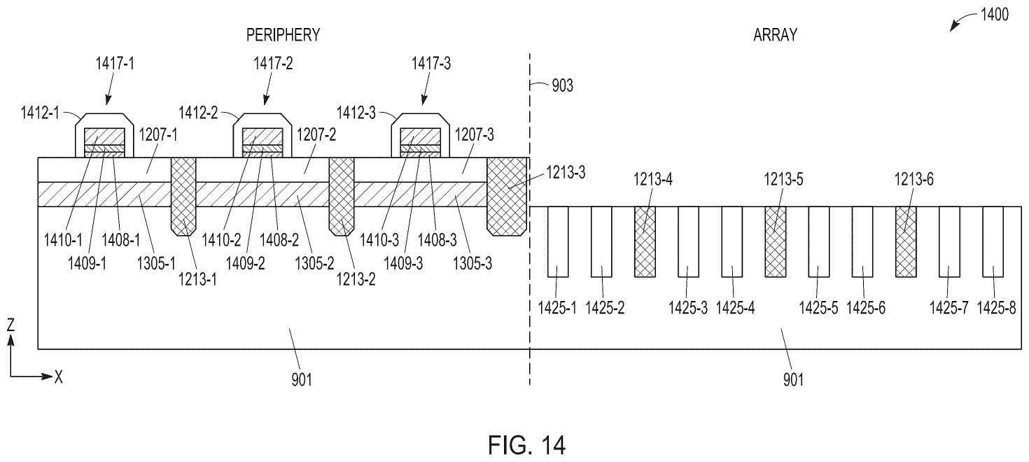

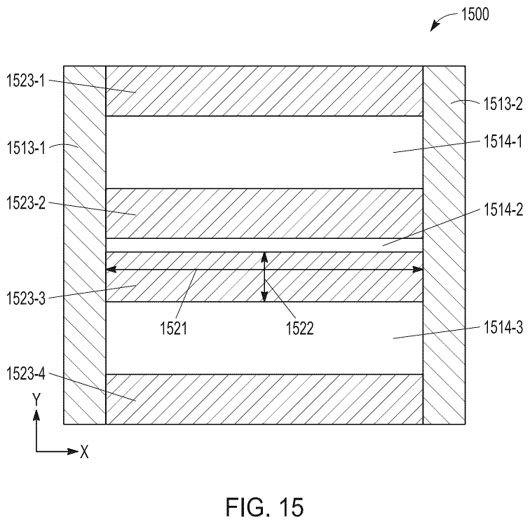

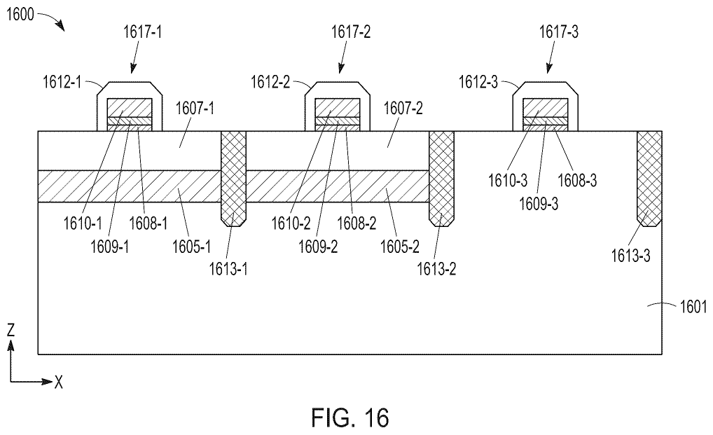

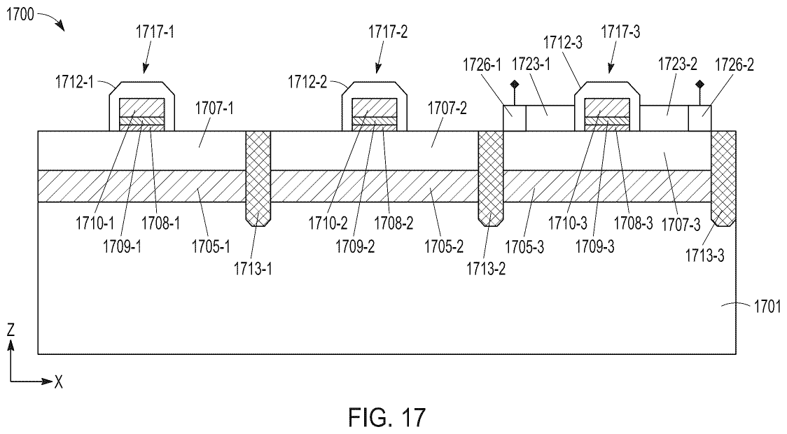

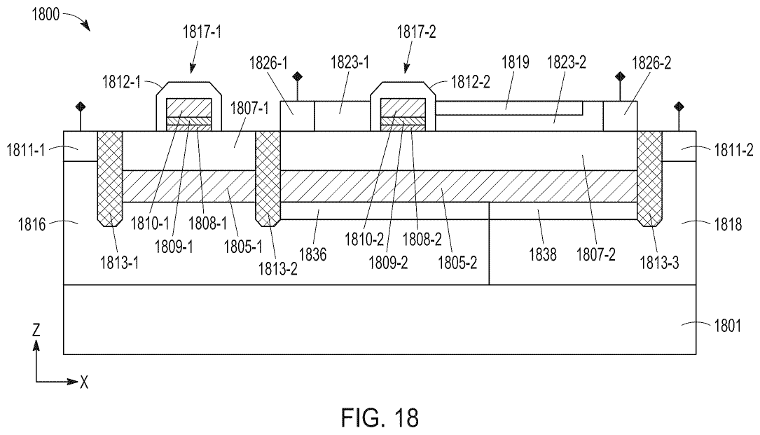

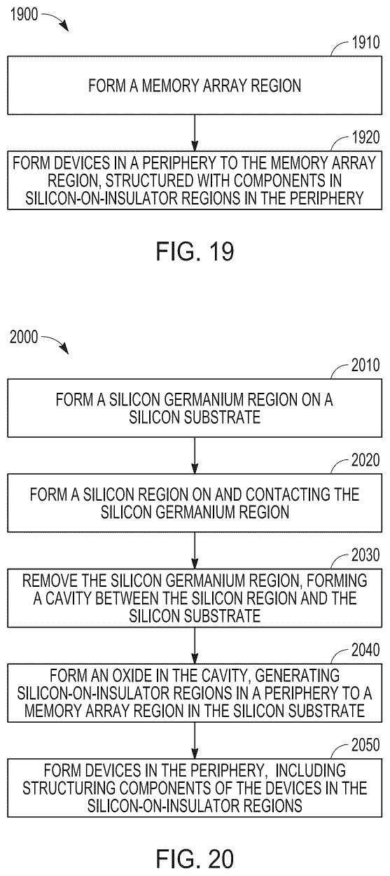

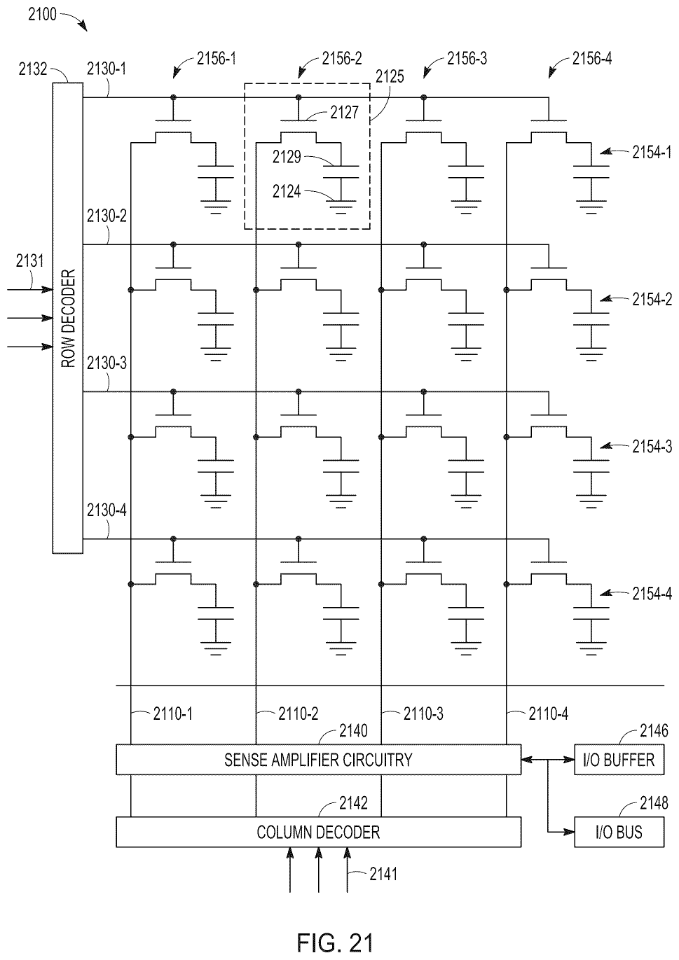

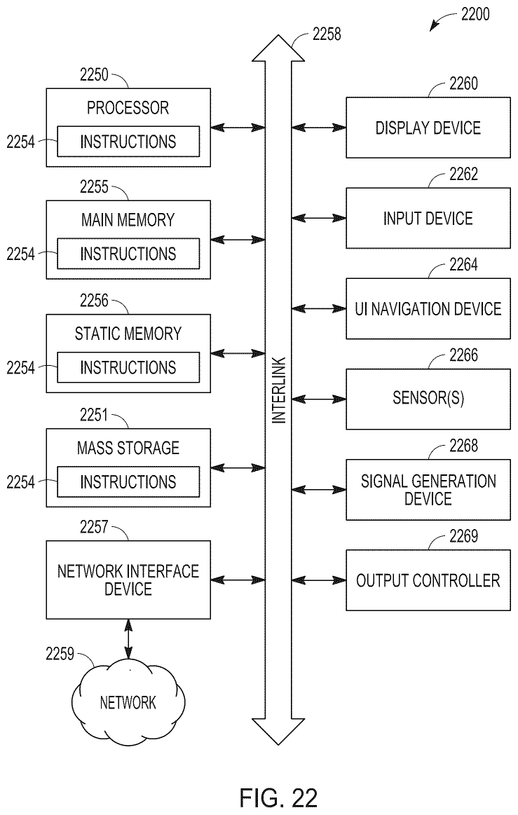

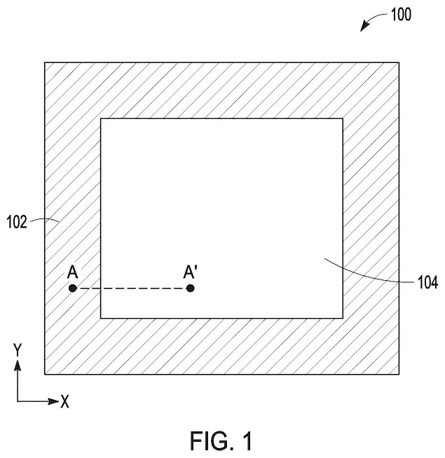

FIG. 1 represents a top view of an embodiment of an example memory device 100 having a memory array region 104 and a periphery 102 to memory array region 104. The top view is shown in the x-direction and the y-direction. Periphery 102 can include semiconductor on insulator, such as SOI, for pitch circuits or periphery circuits, which circuits can include CMOS devices and other devices. Pitch circuits include circuits which can have dimensions aligned with the memory array, such as word line drivers, sense amplifiers, or other similar circuits. Periphery circuits include other logic-like device components that basically control the memory circuits of the memory device. The component devices of the memory array region 104, such as but not limited to memory cells, can be structured on a bulk Si substrate. With the memory array devices structured on the bulk Si substrate, formation of devices on SOI in the non-array region can be implemented with no changes for array integration with the devices in the non-array region.

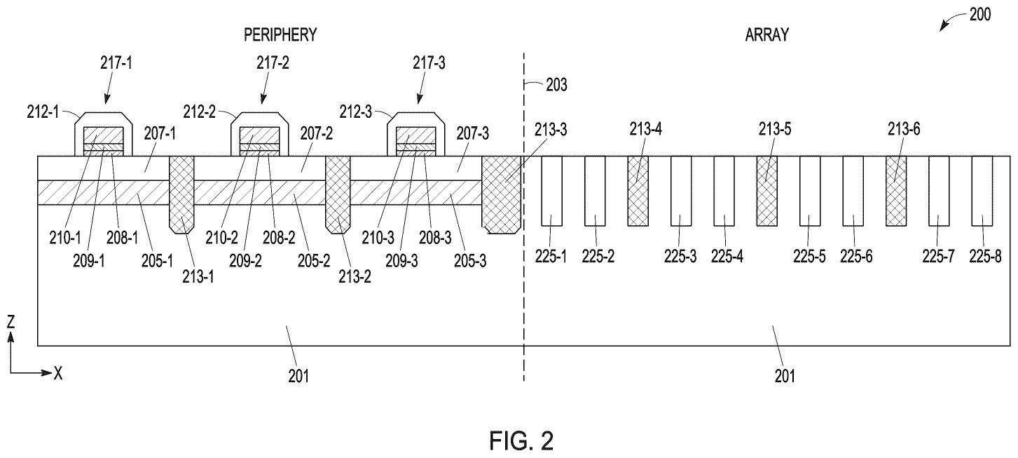

FIG. 2 is a representation of a cross-sectional view of an embodiment of an example structure 200 of memory device 100 of FIG. 1 along a cut-line A-A′. The cross-sectional view is shown in the x-direction and the z-direction. Structure 200 includes a portion of the periphery 102 of memory device 100 and a portion memory array region 104 of memory device 100. In the periphery, structure 200 can include transistors 217-1, 217-2, and 217-3. Transistor 217-1 can include a gate dielectric 208-1 on a channel structure in silicon 207-1 on insulator 205-1 on a Si substrate 201, with a gate 209-1 on gate dielectric 208-1 and a metal 210-1 on gate 209-1, where a dielectric spacer 212-1 covers the top of metal 210-1 and the sides of metal 210-1, gate 209-1, and gate dielectric 208-1. Transistor 217-2 can include a gate dielectric 208-2 on a channel structure in silicon 207-2 on insulator 205-2 on Si substrate 201, with a gate 209-2 on gate dielectric 208-2 and a metal 210-2 on gate 209-2, where a dielectric spacer 212-2 covers the top of metal 210-2 and the sides of metal 210-2, gate 209-2, and gate dielectric 208-2. Transistor 217-3 can include a gate dielectric 208-3 on a channel structure in silicon 207-3 on insulator 205-3 on Si substrate 201, with a gate 209-3 on gate dielectric 208-3 and a metal 210-3 on gate 209-3, where a dielectric spacer 212-3 covers the top of metal 210-3 and the sides of metal 210-3, gate 209-3, and gate dielectric 208-3. A shallow trench isolation (STI) 213-1 can separate transistor 217-1 from transistor 217-2 and a STI 213-2 can separate transistor 217-2 from transistor 217-3. A STI 213-3 can be located at an interface 203 between the periphery and the array.

Though structure 200 shows three transistors, periphery 102 of memory device 100 can include significantly more than three transistors built on SOI in periphery 102. The SOI on Si substrate 201 can be limited to periphery 102 of memory device 100 with components of memory array region 104, such as memory cells, built on Si substrate 201. The SOI on SI substrate can be constructed in periphery 102 to be beneath the pitch circuits or the periphery circuits of memory device 100, where the SOI provides global SOI for these circuits and can be modified to isolate conductive devices in these circuits. For example, a global SOI can be formed and processed for structure 200 with STIs 213-1, 213-2, and 213-3 to form individual SOIs of the combination of silicon 207-1 on insulator 205-1, silicon 207-2 on insulator 205-2, and silicon 207-3 on insulator 205-3, providing isolation of transistors 217-1, transistor 217-2, and transistor 217-3 from each other, with the exception of possible conductive coupling made depending on the design of the circuits in which these transistors are constructed. Silicon 207-1 on insulator 205-1, silicon 207-2 on insulator 205-2, and silicon 207-3 on insulator 205-3 can be located above a bottom level of STIs 213-1 and 213-1 that separate the devices from each other in periphery 102. Transistors 217-1, 217-2, and 217-3 or other devices in periphery 102 of memory device 100 in can be implemented on and in SOI as a HP-CMOS device, a low-voltage CMOS device, a high-voltage CMOS device, a FinFET, a NSFET, a PD-SOI device, a FD-SOI device, a UTBB FD-SOI MOS transistor, or other devices. A HP-CMOS device can provide a higher speed and lower power device as compared with conventional CMOS devices similarly situated. A HP-CMOS device in SOI, as taught herein, in a DRAM, for example, can provide a 30% to 40% improvement in speed or power compared to a bulk CMOS device in a DRAM.

The array portion of structure 200 can include memory cell components 225-1, 225-2, 225-3, 225-4, 225-5, 225-6, 225-7, and 225-8. Such memory cell components can include portions of active areas of access transistors for the memory device such as, but not limited to, a DRAM. A STI 213-4 can separate memory cell components 225-1 and 225-2 from memory cell components 225-3 and 225-4. A STI 213-5 can separate memory cell components 225-3 and 225-4 from memory cell components 225-5 and 225-6. A STI 213-6 can separate memory cell components 225-5 and 225-6 from memory cell components 225-7 and 225-8.

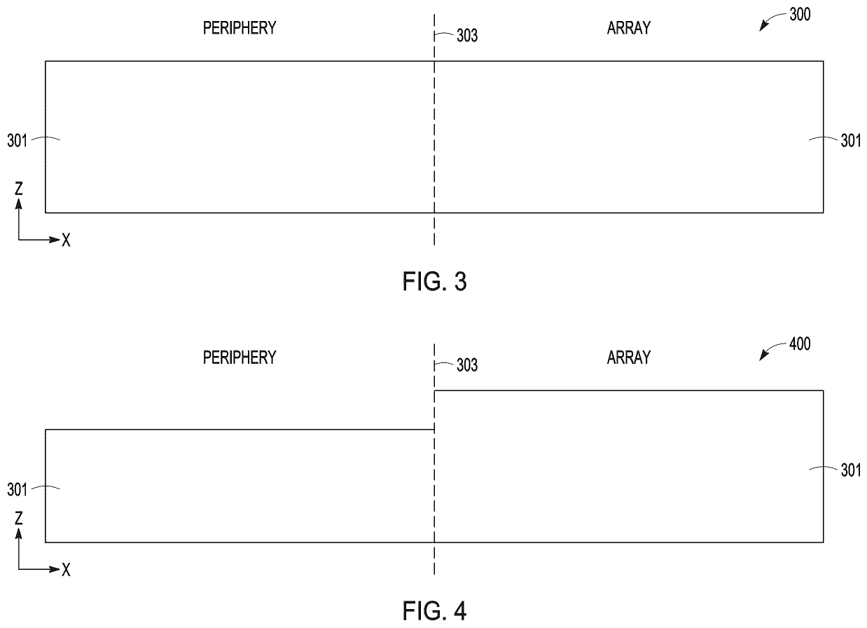

FIGS. 3-8 illustrate an embodiment of an example process flow for fabricating a memory device having a periphery to an array in which the periphery include component devices of the memory device constructed in portions of a global semiconductor on insulator. This example process flow can be used to form a structure similar to structure 200 of memory device 100 of FIG. 1. FIG. 3 illustrates a cross-sectional view of a structure 300 having a substrate 301 with at least a portion of periphery to at least a portion of an array for a memory device being formed on substrate 301. The cross-sectional view is shown in the x-direction and the z-direction. The periphery interfaces the array at a location 303. Substrate 301 can be a Si substrate. For a semiconductor on insulator structure, a semiconductor different from silicon can be used with a corresponding substrate different from a Si substrate.

FIG. 4 illustrates a cross-sectional view of a structure 400, having an array and a periphery, after processing structure 300 of FIG. 3. Material of substrate 301 has been removed from the periphery without removing material from the array. For a Si substrate, silicon can be etched from the Si substrate, while protecting the silicon of the array of structure 300 of FIG. 3.

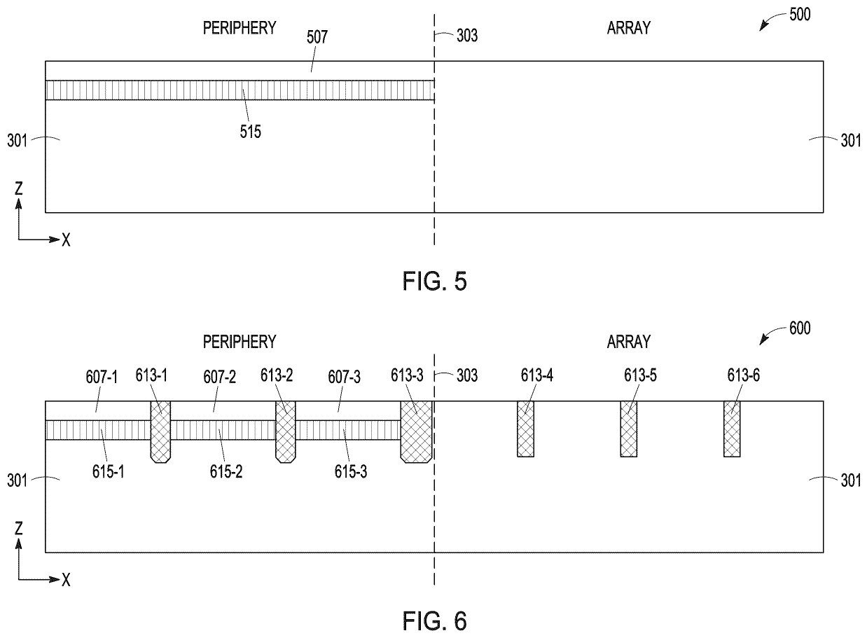

FIG. 5 illustrates a cross-sectional view of a structure 500, having an array and a periphery, after processing structure 400 of FIG. 4. A layer 515 has been formed on the exposed surface of substrate 301 of structure 400 in the periphery as a layer that is epitaxial to the material of substrate 301. With substrate 301 being a Si substrate, layer 515 can be silicon germanium (SiGe) epitaxial layer. A layer 507 of material can be formed on layer 515 as a layer that is epitaxial to the material of layer 515. For layer 515 formed as epitaxial SiGe, layer 507 can be epitaxial Si.

FIG. 6 illustrates a cross-sectional view of a structure 600, having an array and a periphery, after processing structure 500 of FIG. 5. STIs 613-1, 612-2, and 613-3 have been formed in the periphery, extending from the top surface of layer 507 of structure 500 of FIG. 5 to or below the bottom surface of layer 515 of structure 500. STIs 613-1, 612-2, and 613-3 arrange layer 507 on layer 515 of structure 500 into multiple regions including layer 607-1 on layer 615-1, layer 607-2 on layer 615-2, and layer 607-3 on layer 615-3. Formation of STIs 613-1, 612-2, and 613-3 in the periphery can be a partial formation since the STIs are formed from only from one side and at a distance on the other side in the y-direction trenches are to be etched out.

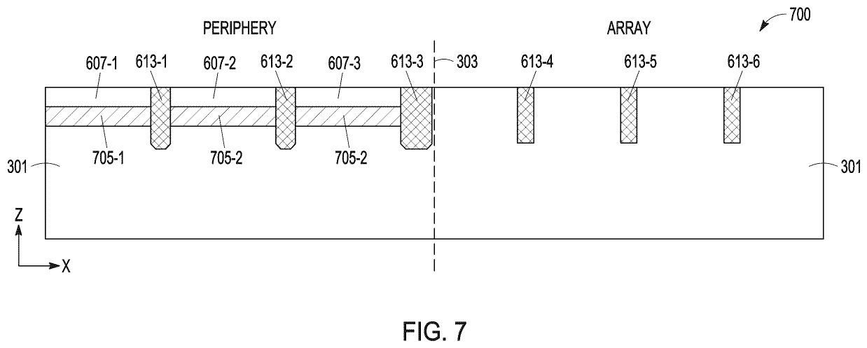

FIG. 7 illustrates a cross-sectional view of a structure 700, having an array and a periphery, after processing structure 600 of FIG. 6. Trenches have been etched out and the material of layers 615-1, 615-2, and 615-3 have been exhumed using the trenches, forming cavities between layers 607-1, 607-2, and 607-3 and substrate 301. The exhuming process can be conducted using a wet etch chemistry. It can be performed using a gas phase chemistry in a reactor, for example, using a hydrogen chloride (HCL) gas. Another technique can include using a downstream plasma in which material of layers 615-1, 615-2, and 615-3 is selective to the material of layers 607-1, 607-2, and 607-3. Insulator material has been formed in the cavities, forming layer 607-1 on insulator layer 705-1, layer 607-2 on insulator layer 705-2, and layer 607-3 on insulator layer 705-3. The insulator material can be an oxide such as a silicon oxide. With the material of layers 607-1, 607-2, and 607-3 being epitaxial silicon, layers 607-1, 607-2, and 607-3 are SOI layers.

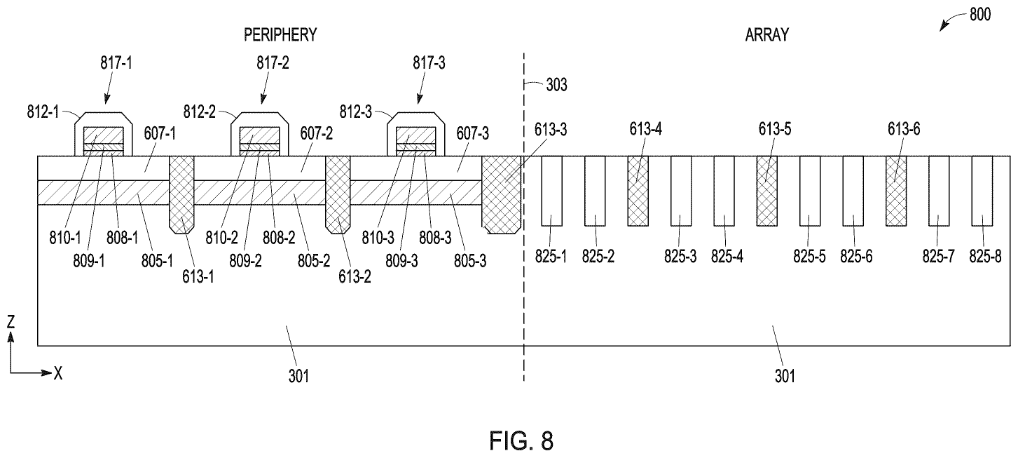

FIG. 8 illustrates a cross-sectional view of a structure 800, having an array and a periphery, after processing structure 700 of FIG. 7. Transistors 817-1, 817-2, and 817-3 have been formed in the periphery and memory cell components 825-1, 825-2, 825-3, 825-4, 825-5, 825-6, 825-7, and 825-8 have been formed for the array of the memory device being formed. Such memory cell components can include portions of active areas of access transistors for the memory device such as, but not limited to, a DRAM device. Memory cell components 825-1 and 825-2 and memory cell components 825-3 and 825-4 have been formed on opposite sides of STI 613-4. Memory cell components 825-3 and 825-4 and components 825-5 and 825-6 have been formed on opposite sides of STI 613-5. Memory cell components 825-5 and 825-6 and memory cell components 825-7 and 825-8 have been formed on opposite sides of STI 613-6.

In the process flow of FIGS. 3-8, the generated semiconductor on insulator regions, which can be realized by SOI regions, can be contained entirely in the periphery. With generated SOI regions, transistor 817-1 has been formed with components in SOI formed by layer 607-1 on insulator layer 705-1. Transistor 817-1 has been formed having a gate dielectric 808-1 on a channel structure in layer 607-1 on insulator layer 705-1 on substrate 301. The channel structure in layer 607-1 can couple two source/drain regions in layer 607-1. A gate 809-1 has been formed on gate dielectric 808-1 and a metal 810-1 on gate 809-1. A dielectric spacer 812-1 has been formed that covers the top of metal 810-1 and the sides of metal 810-1, gate 809-1, and gate dielectric 808-1. Transistor 817-2 has been formed with components in SOI formed by layer 607-2 on insulator layer 705-2. Transistor 817-2 has been formed having a gate dielectric 808-2 on a channel structure in layer 607-2 on insulator layer 705-2 on substrate 301. The channel structure in layer 607-2 can couple two source/drain regions in layer 607-2. A gate 809-2 has been formed on gate dielectric 808-2 and a metal 810-2 on gate 809-2. A dielectric spacer 812-2 has been formed that covers the top of metal 810-2 and the sides of metal 810-2, gate 809-2, and gate dielectric 808-2. Transistor 817-3 has been formed with components in SOI formed by layer 607-3 on insulator layer 705-3. Transistor 817-3 has been formed having a gate dielectric 808-3 on a channel structure in layer 607-3 on insulator layer 705-3 on substrate 301. The channel structure in layer 607-3 can couple two source/drain regions in layer 607-3. A gate 809-3 has been formed on gate dielectric 808-3 and a metal 810-3 on gate 809-3. A dielectric spacer 812-3 has been formed that covers the top of metal 810-3 and the sides of metal 810-3, gate 809-3, and gate dielectric 808-3. These transistors can be structured as part a periphery circuit or a pitch circuit in the periphery of the memory device being constructed.

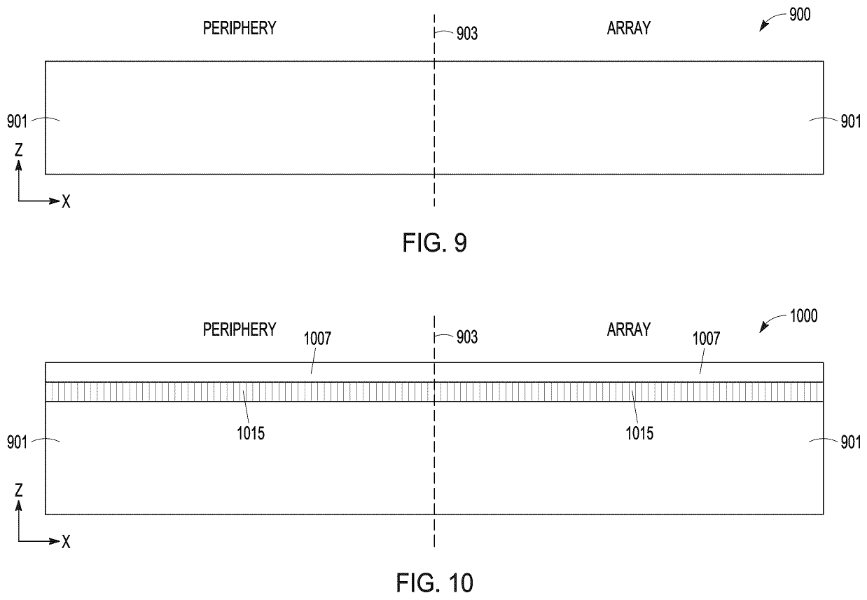

FIGS. 9-14 illustrate an embodiment of another example process flow for fabricating a memory device having a periphery to an array in which the periphery includes component non-memory cell devices of the memory device constructed in portions of a global semiconductor on insulator. This example process flow can be used to form a structure similar to structure 200 of memory device 100 of FIG. 1. FIG. 9 illustrates a cross-sectional view of a structure 900 having a substrate 901 with at least a portion of periphery to at least a portion of an array for a memory device being formed on substrate 901. The cross-sectional view is shown in the x-direction and the z-direction. The periphery interfaces the array at a location 903. Substrate 901 can be a Si substrate. For a semiconductor on insulator structure, a semiconductor different from silicon can be used with a corresponding substrate different from a Si substrate.

FIG. 10 illustrates a cross-sectional view of a structure 1000, having an array and a periphery, after processing structure 900 of FIG. 9. A layer 1015 has been formed on the top surface of structure 900 of FIG. 9 in both the periphery and in the array for the memory device being formed. The material of layer 1015 can be a material that can be formed epitaxially with substrate 901. For substrate 901 being a Si substrate, the material of layer 1015 can be epitaxial SiGe. A layer 1007 has been formed on the tup surface of layer 1015 in both the periphery and in the array for the memory device being formed. The material of layer 1007 can be a material that can be formed epitaxially on layer 1015. For the material of layer 1015 being an epitaxial SiGe, the material of layer 1007 can be epitaxial Si. This process flow may have the advantage, with respect to the process flow of FIGS. 3-8, that the epitaxial depositions do not have to be selective depositions, since the epitaxial layers are formed in both the periphery and the array.

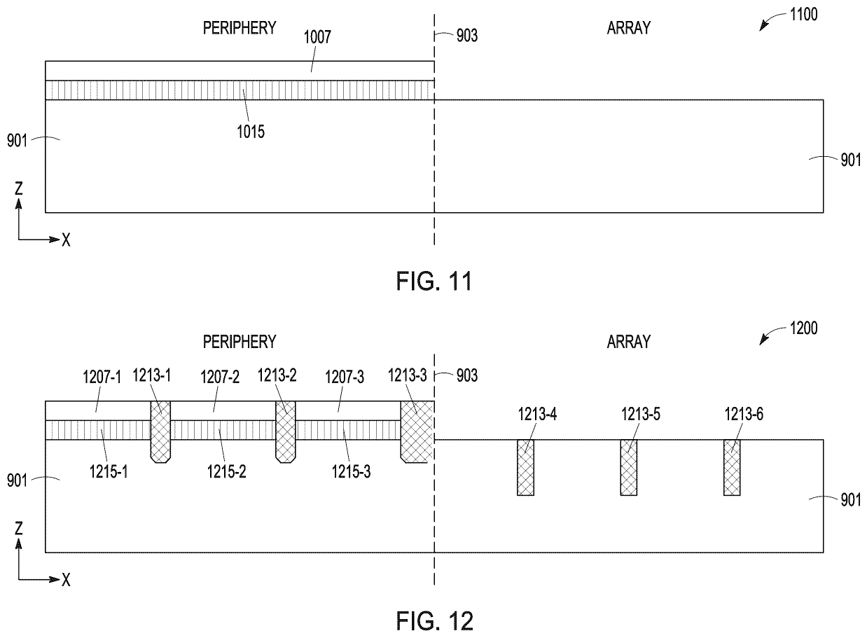

FIG. 11 illustrates a cross-sectional view of a structure 1100, having an array and a periphery, after processing structure 1000 of FIG. 10. Portions of layer 1015 and layer 1007 in the array have been removed from the area for which the array of the memory device is being formed. Layer 1015 and layer 1007 can be completely removed from the array, while maintaining the portions of layer 1015 and layer 1007 that are located in the periphery.

FIG. 12 illustrates a cross-sectional view of a structure 1200, having an array and a periphery, after processing structure 1100 of FIG. 11. STIs 1213-1, 1212-2, and 1213-3 have been formed in the periphery, extending from the top surface of layer 1007 of structure 1100 of FIG. 11 to or below the bottom surface of layer 1015 of structure 1100. STIs 1213-1, 1212-2, and 1213-3 arrange layer 1007 on layer 1015 into multiple regions having layer 1207-1 on layer 1215-1, layer 1207-2 on layer 1215-2, and layer 1207-3 on layer 1215-3. Formation of STIs 1213-1, 1212-2, and 1213-3 in the periphery can be a partial formation since the STIs are formed from only from one side and at a distance on the other side in the y-direction trenches are to be etched out. STIs 1213-4, 1213-5, and 1213-6 have been formed in substrate 901 for the array.

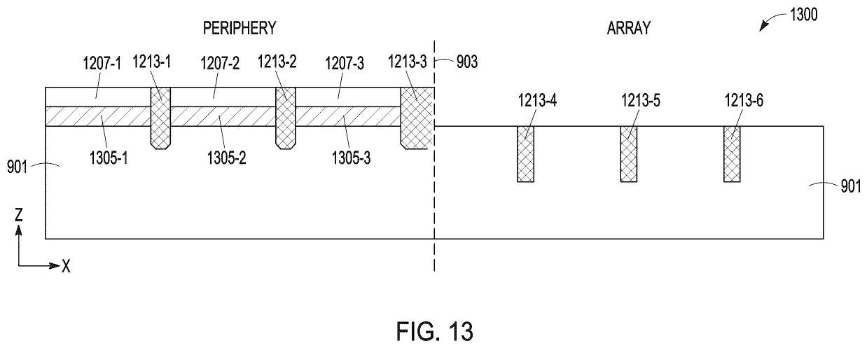

FIG. 13 illustrates a cross-sectional view of a structure 1300, having an array and a periphery, after processing structure 1200 of FIG. 12. Trenches have been etched out in the periphery and the material of layers 1215-1, 1215-2, and 1215-3 have been exhumed using the trenches, forming cavities between layers 1207-1, 1207-2, and 1207-3 and substrate 901. Insulator material has been formed in the cavities, forming layer 1207-1 on insulator layer 1305-1, layer 1207-2 on insulator layer 1305-2, and layer 1207-3 on insulator layer 1305-3. The insulator material can be an oxide such as a silicon oxide. With the material of layers 1207-1, 1207-2, and 1207-3 being epitaxial Si, layers 1207-1, 1207-2, and 1207-3 on insulator layer 1305-1, insulator layer 1305-2, and insulator layer 1305-3, respectively, are SOI layers.

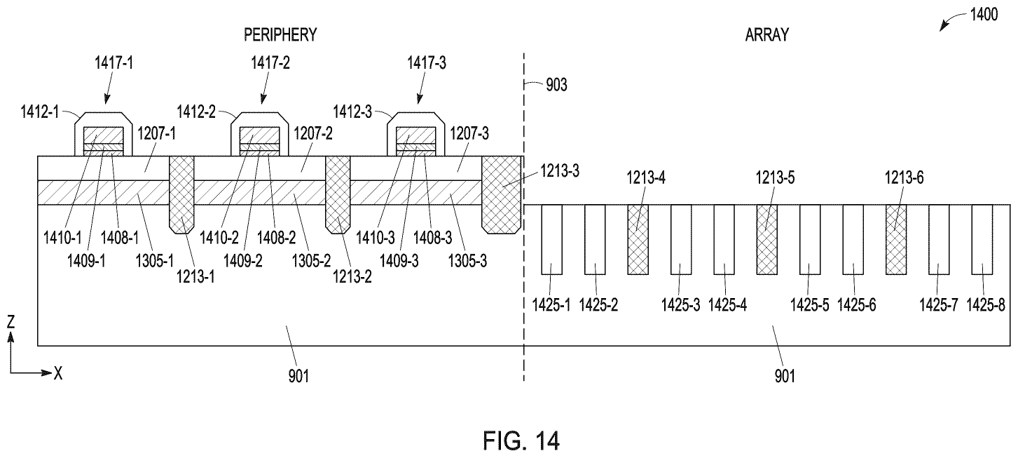

FIG. 14 illustrates a cross-sectional view of a structure 1400, having an array and a periphery, after processing structure 1300 of FIG. 13. Transistors 1417-1, 1417-2, and 1417-3 have been formed in the periphery and memory cell components 1425-1, 1425-2, 1425-3, 1425-4, 1425-5, 1425-6, 1425-7, and 1425-8 have been formed for the array of the memory device being formed. Such memory cell components can include portions of active areas of access transistors for the memory device such as, but not limited to, a DRAM device. Memory cell components 1425-1 and 1425-2 and memory cell components 1425-3 and 1425-4 have been formed on opposite sides of STI 1213-4. Memory cell components 1425-3 and 1425-4 and components 1425-5 and 1425-6 have been formed on opposite sides of STI 1213-5. Memory cell components 1425-5 and 1425-6 and memory cell components 1425-7 and 1425-8 have been formed on opposite sides of STI 1213-6.

In the process flow of FIGS. 9-14, the generated semiconductor on insulator regions, which can be realized by SOI regions, can be contained entirely in the periphery. With generated SOI regions, transistor 1417-1 has been formed with components in SOI formed by layer 1207-1 on insulator layer 1305-1. Transistor 1417-1 has been formed having a gate dielectric 1408-1 on a channel structure in layer 1207-1 on insulator layer 1305-1 on substrate 901. The channel structure in layer 1207-1 can couple two source/drain regions in layer 1207-1. A gate 1409-1 has been formed on gate dielectric 1408-1 and a metal 1410-1 on gate 1409-1. A dielectric spacer 1412-1 has been formed that covers the top of metal 1410-1 and the sides of metal 1410-1, gate 1409-1, and gate dielectric 1408-1. Transistor 1417-2 has been formed with components in SOI formed by layer 1207-2 on insulator layer 1305-2. Transistor 1417-2 has been formed having a gate dielectric 1408-2 on a channel structure in layer 1207-2 on insulator layer 1305-2 on substrate 901. The channel structure in layer 1207-2 can couple two source/drain regions in layer 1207-2. A gate 1409-2 has been formed on gate dielectric 1408-2 and a metal 1410-2 on gate 1409-2. A dielectric spacer 1412-2 has been formed that covers the top of metal 1410-2 and the sides of metal 1410-2, gate 1409-2, and gate dielectric 1408-2. Transistor 1417-3 has been formed with components in SOI formed by layer 1207-3 on insulator layer 1305-3. Transistor 1417-3 has been formed having a gate dielectric 1408-3 on a channel structure in layer 1207-3 on insulator layer 1305-3 on substrate 301. The channel structure in layer 1207-3 can couple two source/drain regions in layer 1207-3. A gate 1409-3 has been formed on gate dielectric 1408-3 and a metal 1410-3 on gate 1409-3. A dielectric spacer 1412-3 has been formed that covers the top of metal 1410-3 and the sides of metal 1410-3, gate 1409-3, and gate dielectric 1408-3. These transistors can be structured as part a periphery circuit or a pitch circuit.

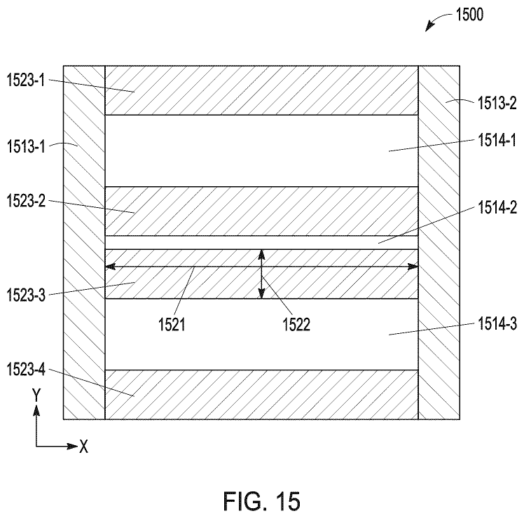

FIG. 15 shows a top view of a structure 1500 in an embodiment of an example periphery for forming component devices of periphery circuits or pitch circuits for a memory device. Active area 1523-1 and active area 1523-2 can be separated by STI 1514-1. Active area 1523-2 and active area 1523-3 can be separated by STI 1514-2. Active area 1523-3 and active area 1523-4 can be separated by STI 1514-3. Active areas 1523-1, 1523-2, 1523-3, and 1523-4 and STIs 1514-1, 1514-2, and 1514-3 can be bounded by insulation layers 1513-1 and 1513-2. Depending on the active devices being formed in the periphery, STI formation may vary as shown in FIG. 15. The active areas can be subdivided into small, measurable increments for proper SOI formation, where the increments can be defined by lengths 1522 and 1521 for each active area. For the process flows discussed above using epitaxial SiGe and Si, lateral spacing of STIs for exhuming SiGe can be used for supporting STI to STI spacing without significant tapering of the edges of the Si. The selection of values for 1522 and 1521 can be strong function of the percent SiGe and the SiGe to Si thickness ratios.

Various deposition techniques for components of structures 300-800 in the process flow of FIGS. 3-8 and for components of structures 900-1400 in the process flow of FIGS. 9-14 can be used that are typical for the material being formed, the dimensions of the material being formed, and the architecture in which the material is being formed. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in forming STIs using an active area mask on an island for active areas after forming gate stacks and source/drains associated with the gate stacks, as taught herein.

The devices in the periphery to the memory array can be structured in a number of different formats. One format of devices in the periphery can include low-voltage transistors in SOI as shown in FIG. 2. Low-voltage devices in a memory device can be structured to operate at voltages corresponding to logic levels as used in memory cells. Another format of devices in the periphery can include a number of low-voltage transistors structured in SOI and high-voltage transistors structured in the bulk substrate. High-voltage devices in a memory device can be structured to operate at voltages larger than logic levels to operate drivers in the memory device. Another format of devices in the periphery can include a number of low-voltage transistors structured in SOI and high-voltage transistors structured in SOI, with the high-voltage transistors having shifted sourced/drain regions. Another format of devices in the periphery can include a number of low-voltage transistors structured in SOI and high-voltage transistors structured in SOI on ground planes.

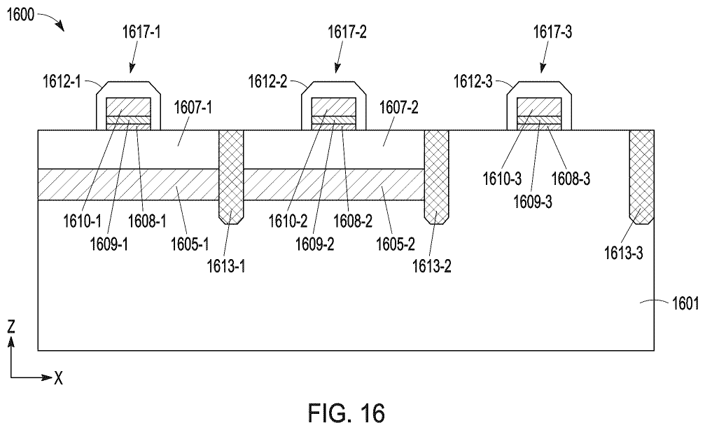

FIG. 16 is a representation of a cross-sectional view of an embodiment of an example structure 1600 in the periphery to a memory array of a memory device having a high-voltage transistor 1617-3 structured in a bulk Si substrate 1601. Structure 1600 can include low-voltage transistors 1617-1 and 1617-2 in SOI along with high-voltage transistor 1617-3 in bulk Si substrate 1601. In an example, transistor 1617-1 can be a n-type transistor or a p-type transistor in a periphery circuit and transistor 1617-2 can be a n-type transistor or a p-type transistor in a sense amplifier, an equalizer, an input/output (I/O), or other device in a pitch circuit. Transistor 1617-3 can be implemented as a high-voltage transistor using thicker dimensions than the dimensions of transistors 1617-1 and 1617-2. Other permutations of device types, including CMOS devices, can be implemented in a structure similar to structure 1600.

Transistor 1617-1 can include a gate dielectric 1608-1 on a channel structure in Si 1607-1 on insulator 1605-1 on a Si substrate 1601, with a gate 1609-1 on gate dielectric 1608-1 and a metal 1610-1 on gate 1609-1. The channel structure in Si 1607-1 can couple two source/drain regions in Si 1607-1. A dielectric spacer 1612-1 can cover the top of metal 1610-1 and the sides of metal 1610-1, gate 1609-1, and gate dielectric 1608-1. Transistor 1617-2 can include a gate dielectric 1608-2 on a channel structure in Si 1607-2 on insulator 1605-2 on Si substrate 1601, with a gate 1609-2 on gate dielectric 1608-2 and a metal 1610-2 on gate 1609-2. The channel structure in Si 1607-2 can couple two source/drain regions in Si 1607-2. A dielectric spacer 1612-2 can cover the top of metal 1610-2 and the sides of metal 1610-2, gate 1609-2, and gate dielectric 1608-2.

Transistor 1617-3 can include a gate dielectric 1608-3 on a channel structure in Si substrate 1601, with a gate 1609-3 on gate dielectric 1608-3 and a metal 1610-3 on gate 1609-3. The channel structure in Si substrate 1601 can couple two source/drain regions in Si substrate 1601. A dielectric spacer 1612-3 covers the top of metal 1610-3 and the sides of metal 1610-3, gate 1609-3, and gate dielectric 1608-3. A shallow trench isolation (STI) 1613-1 can separate transistor 1617-1 from transistor 1617-2 and a STI 1613-2 can separate transistor 1617-2 from transistor 1617-3. A STI 1613-3 can be located at an interface at a boundary of structure 1600.

Though structure 1600 shows three transistors, a periphery including structure 1600 can include significantly more than three transistors with a number of low-voltage transistors built in SOI and a number of high-voltage transistors in bulk Si substrate 1601. The SOI on Si substrate 1601 can be limited to the periphery of the memory device. The SOI on SI substrate can be constructed in the periphery to be beneath the pitch circuits or the periphery circuits of the memory device, where the SOI provides global SOI that can be modified. With the high-voltage transistors in bulk Si substrate, the low-voltage transistors in the periphery can be constructed bulk substrate using selective SOI formation.

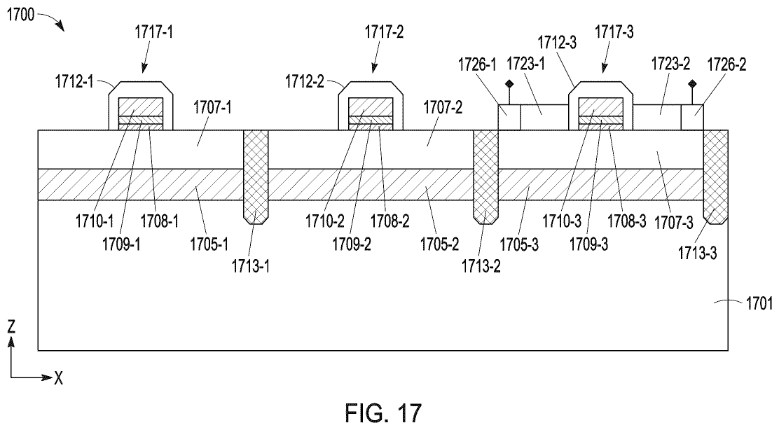

FIG. 17 is a representation of a cross-sectional view of an embodiment of an example structure 1700 in the periphery to a memory array of a memory device, with the periphery having a high-voltage transistor 1717-3 structured in SOI. Structure 1700 can include low-voltage transistors 1717-1 and 1717-2 in SOI along with high-voltage transistor 1717-3 in SOI. A shallow trench isolation (STI) 1713-1 can separate transistor 1717-1 from transistor 1717-2 and a STI 1713-2 can separate transistor 1717-2 from transistor 1717-3. A STI 1713-3 can be located at an interface at a boundary of structure 1700. Transistor 1717-1 can be a n-type transistor or a p-type transistor in a periphery circuit and transistor 1717-2 can be a n-type transistor or a p-type transistor in a sense amplifier, an equalizer, an input/output (I/O), or other device in a pitch circuit. Transistor 1717-3 can be implemented as a high-voltage transistor using thicker dimensions than the dimensions of transistors 1717-1 and 1717-2. Other permutations of device types, including CMOS devices, can be implemented in a structure similar to structure 1700.

Transistor 1717-1 can include a gate dielectric 1708-1 on a channel structure in Si 1707-1 on insulator 1705-1 on a Si substrate 1701, with a gate 1709-1 on gate dielectric 1708-1 and a metal 1710-1 on gate 1709-1. The channel structure in Si 1707-1 can couple two source/drain regions in Si 1707-1. A dielectric spacer 1712-1 can cover the top of metal 1710-1 and the sides of metal 1710-1, gate 1709-1, and gate dielectric 1708-1. Transistor 1717-2 can include a gate dielectric 1708-2 on a channel structure in Si 1707-2 on insulator 1705-2 on Si substrate 1701, with a gate 1709-2 on gate dielectric 1708-2 and a metal 1710-2 on gate 1709-2. The channel structure in Si 1707-2 can couple two source/drain regions in Si 1707-2. A dielectric spacer 1712-2 can cover the top of metal 1710-2 and the sides of metal 1710-2, gate 1709-2, and gate dielectric 1708-2.

Transistor 1717-3 can include a gate dielectric 1708-3 on a channel structure in Si 1707-3 on insulator 1705-1 on a Si substrate 1701, with a gate 1709-3 on gate dielectric 1708-3 and a metal 1710-3 on gate 1709-3. A dielectric spacer 1712-3 covers the top of metal 1710-3 and the sides of metal 1710-3, gate 1709-3, and gate dielectric 1708-3. Transistor 1717-3 can include raised drift regions 1723-1 and 1723-2 that provide shifted source/drains, where the majority carrier concentration of drain regions 1723-1 and 1723-2 depends on the carrier type of transistor 1717-3. Raised drift regions 1723-1 and 1723-2 are coupled to nodes external to transistor 1717-3 by contact regions 1726-1 and 1726-2, respectively, which can be n-type or p-type contact regions depending on the charge type of their respective raised drift regions 1723-1 and 1723-2. Raised drift regions 1723-1 and 1723-2 can be constructed with an additional epitaxial deposition to the flow process of FIGS. 3-8 or FIGS. 9-14. Construction of raised drift regions 1723-1 and 1723-2 can include a symmetric option or a asymmetric option depending on specifications for on-resistance, back bias voltage, or area.

Though structure 1700 shows three transistors, a periphery including structure 1700 can include significantly more than three transistors with a number of low-voltage transistors built in SOI and a number of high-voltage transistors in SOI similar to transistor 1717-3. The SOI on Si substrate 1701 can be limited to the periphery of the memory device. The SOI on SI substrate can be constructed in the periphery to be beneath the pitch circuits or the periphery circuits of the memory device, where the SOI provides global SOI.

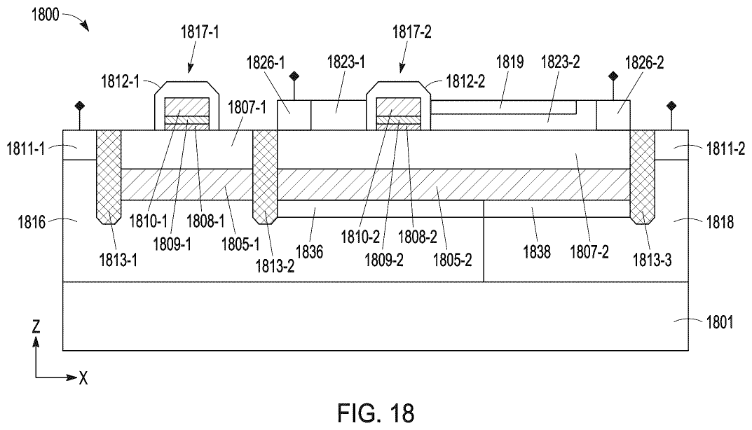

FIG. 18 is a representation of a cross-sectional view of an embodiment of an example structure 1800 in the periphery to a memory array of a memory device, with the periphery having a high-voltage transistor 1817-2 structured in semiconductor on insulator. Structure 1800 can include low-voltage transistor 1817-1 in SOI along with high-voltage transistor 1817-2 in SOT. A STI 1813-1 and STI 1813-2 isolate transistor 1817-1 in structure 1800. STI 1813-2 and a STI 1813 isolate transistor 1817-2 in structure 1800. Transistor 1817-1 can be a n-type transistor or a p-type transistor in a periphery circuit or in a pitch circuit. Transistor 1817-2 can be implemented as a high-voltage transistor using thicker dimensions than the dimensions of transistor 1817-1. Other permutations of device types, including CMOS devices, can be implemented in a structure similar to structure 1800.

Transistor 1817-1 can include a gate dielectric 1808-1 on a channel structure in Si 1807-1 on insulator 1805-1 on a Si substrate 1801, with a gate 1809-1 on gate dielectric 1808-1 and a metal 1810-1 on gate 1809-1. The channel structure in Si 1807-1 can couple two source/drain regions in Si 1807-1. A dielectric spacer 1812-1 can cover the top of metal 1810-1 and the sides of metal 1810-1, gate 1809-1, and gate dielectric 1808-1.

Transistor 1817-2 can include a gate dielectric 1808-2 on a channel structure in Si 1807-2 on insulator 1805-2 on Si substrate 1801, with a gate 1809-2 on gate dielectric 1808-2 and a metal 1810-2 on gate 1809-3. A dielectric spacer 1812-2 can cover the top of metal 1810-2 and the sides of metal 1810-2, gate 1809-2, and gate dielectric 1808-2. Insulator 1805-2 can be located on and contacting a p-type ground plane 1836 and on and contacting a n-type ground plane 1838. Ground plane 1836 and ground plane 1838 can be connected together and can be arranged between STI 1813-2 and a STI 1813. Ground plane 1836 can be located in a p-type well 1816 in Si substrate 1801, where insulator 1805-1 is disposed on p-type well 1816. An external node is coupled to p-type well 1816 by a p+ contact 1811-1. Ground plane 1838 can be located in a n-type well 1818 in Si substrate 1801. An external node is coupled to n-type well 1818 by a n+ contact 1811-2.

Transistor 1817-2 can include raised drift regions 1823-1 and 1823-2 that provide shifted source/drains. Raised drift regions 1823-1 and 1823-2 are coupled to nodes external to transistor 1817-2 by n+ contact region 1826-1 and n+ contact region 1826-2. Raised drift region 1823-2 can be a n-type drift region, where a p-type region 1819 is disposed on raised drift region 1823-2. P-type region 1819 on n-type drift region 1823-2 provides a reduced surface field (RESURF) structure. Such a combination of p-type region 1819 on n-type drift region 1823-2 with the dual ground planes 1836 and 1838 can provide a mechanism to increase back bias voltage with a UTBB structure. Raised drift regions 1823-1 and 1823-2 can be constructed with an additional epitaxial deposition to the flow process of FIGS. 3-8 or FIGS. 9-14.

Though structure 1800 shows two transistors, a periphery including structure 1800 can include significantly more than two transistors with a number of low-voltage transistors built in SOI and a number of high-voltage transistors in SOI similar to transistor 1817-2. The SOI on Si substrate 1801 can be limited to the periphery of the memory device. The SOI on SI substrate can be constructed in the periphery to be beneath the pitch circuits or the periphery circuits of the memory device, where the SOI provides global SOI.

In various device structures in the periphery to the memory array for a memory device, use of a PD-SOI device format can include body ties to avoid floating body effect, which can incur an additional area penalty. In various device structures in the periphery to the memory array for a memory device, use of a UTBB FD-SOI device format can be implemented without a body-tied arrangement, which would incur no additional area penalty.

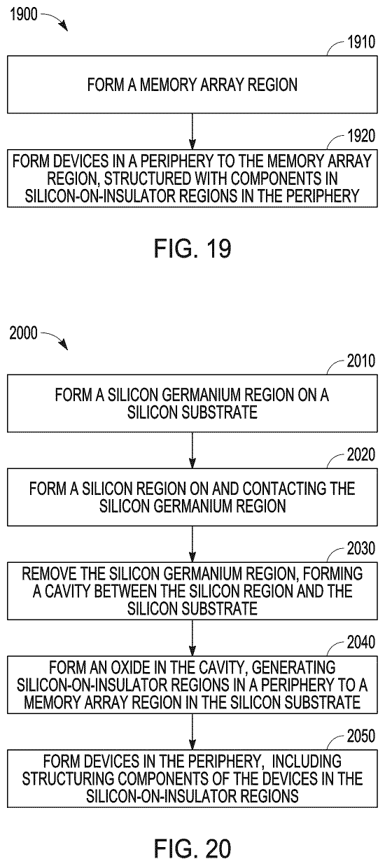

FIG. 19 is a flow diagram of features of an embodiment of an example method 1900 of forming a memory device. At 1910, a memory array region is formed. At 1920, devices are formed in a periphery to the memory array region. The devices are structured with components in silicon on insulator regions in the periphery. The silicon on insulator regions are disposed on a bulk substrate. Memory cells can be formed in the bulk substrate in the memory array region. The silicon on insulator regions can be formed entirely contained in the periphery.

Variations of method 1900 or methods similar to method 1900 can include a number of different embodiments that may be combined depending on the application of such methods or the architecture or process flow of an integrated circuit for which such methods are implemented. Such methods can include forming the silicon on insulator regions and shallow trench insulators such that the silicon on insulator regions are at a level between a top surface of the bulk substrate and a bottom level of the shallow trench insulators. The shallow trench insulators are structured to separate the devices from each other in the periphery.

Variations of method 1900 or methods similar to method 1900 can include maintaining a region in the periphery without having a silicon on insulator region, while forming the silicon on insulator regions in the periphery in which components of the devices are to be formed. A high-voltage device in the bulk substrate can be formed in the region in the periphery without having a silicon on insulator region.

Variations of method 1900 or methods similar to method 1900 can include another formation of a high-voltage device in the periphery. In this variation, the high-voltage device can be structured with components in one silicon on insulator region of the silicon on insulator regions. Such formation can include depositing an epitaxial layer on a top surface of the one silicon on insulator region and forming drift regions in the epitaxial layer.

Variations of method 1900 or methods similar to method 1900 can include another formation of a high-voltage device in the periphery. In this formation, a silicon on insulator region of the silicon on insulator regions in the periphery can be formed on a ground-plane on a p-type well and on another ground plane on a n-type well. A high-voltage device can be formed on the silicon on insulator that is on the ground-plane on the p-type well and on the other ground plane on the n-type well. An example formation of the high-voltage device can include depositing an epitaxial layer on a top surface of the silicon on insulator region and forming drift regions in the epitaxial layer.

In various embodiments, a memory device can include a memory array region and a periphery to the memory array region. The periphery can include devices structured with components in semiconductor on insulator regions in the periphery. The semiconductor on insulator regions can be disposed on, but is different from, a bulk substrate. The semiconductor on insulator regions can be contained entirely in the periphery. The semiconductor on insulator regions can be SOI regions. The SOI regions can be structured on a Si substrate.

Variations of such a memory device and its features, as taught herein, can include a number of different embodiments and features that may be combined depending on the application of such memory devices, the format of such memory devices, and/or the architecture in which such memory devices are implemented. Features of such memory devices can include the semiconductor on insulator regions being located above a bottom level of shallow trench insulators that separate the devices from each other in the periphery.

Variations of such a memory device can include a number of low-voltage devices and high-voltage devices. Such a memory device can include a high-voltage device in the periphery, where the high-voltage device can be structured in the bulk substrate without a component in a semiconductor on insulator region in the periphery. Such a memory device can include a high-voltage device in the periphery, where the high-voltage device can be structured with components in one of the semiconductor on insulator regions and with drift regions on a top surface of the semiconductor on insulator region.

Variations of such a memory device can include a high-voltage device in the periphery, where the high-voltage device can be structured with components in one of the semiconductor on insulator regions, with the one semiconductor on insulator region on a ground-plane on a p-type well and on another ground plane on a n-type well. The high-voltage device can include drift regions on a top surface of the semiconductor on insulator region.

Variations of such a memory device can include the devices in the periphery structured as part a periphery circuit or a pitch circuit. The memory device can be, but is not limited to, a DRAM device.

FIG. 20 is a flow diagram of features of an embodiment of an example method 2000 of forming a memory device. At 2010, a silicon germanium region is formed on a silicon substrate. At 2020, a silicon region is formed on and contacting the silicon germanium region. At 2030, the silicon germanium region is removed. The removal of the silicon germanium forms a cavity between the silicon region and the silicon substrate. At 2040, an oxide is formed in the cavity, generating silicon on insulator regions in a periphery to a memory array region in the silicon substrate. At 2050, devices are formed in the periphery, including structuring components of the devices in the silicon on insulator regions. The devices can be in a periphery circuit or a pitch circuit.

Variations of method 2000 or methods similar to method 2000 can include a number of different embodiments that may be combined depending on the application of such methods or the architecture or process flow of an integrated circuit for which such methods are implemented. Such methods can include, before forming the silicon germanium region and the silicon region, removing a silicon region of the silicon substrate in the periphery to the memory array region of the silicon substrate. The removed region of the silicon substrate can be formed without removing silicon material from the silicon substrate in the memory array region. The silicon germanium region and silicon region on the silicon germanium region can be formed on the silicon substrate in the removed region. Shallow trench insulators can be formed in the silicon region on the silicon germanium region and in the silicon germanium region. The silicon germanium region can be removed and the oxide can be formed to generate the silicon on insulator regions. The silicon on insulator regions can be formed with respect to the shallow trench insulators. The devices can be formed having components of the devices in the silicon on insulator regions, separated by the shallow trench insulators. Memory cells can be formed in the memory array region after generating the silicon on insulator regions.

Variations of method 2000 or methods similar to method 2000 can include forming the silicon germanium region on the silicon substrate in the periphery to the memory array region and in the memory array region. The silicon region can be formed on and contacting the silicon germanium region in the periphery to the memory array region and in the memory array region. The silicon region on and contacting the silicon germanium region and the silicon germanium region in the memory array region can be removed. Shallow trench insulators can be formed in the silicon region on the silicon germanium region and in the silicon germanium region. The silicon germanium region can be removed and the oxide can be formed to generate the silicon on insulator regions. The silicon on insulator regions can be formed with respect to the shallow trench insulators. The devices can be formed having components of the devices in the silicon on insulator regions, separated by the shallow trench insulators.

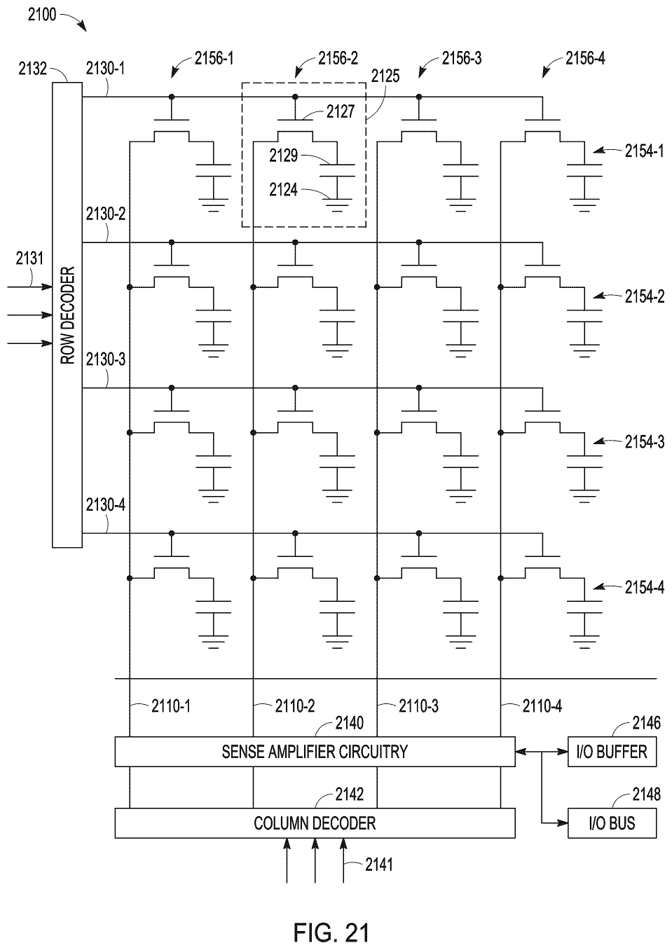

FIG. 21 is a schematic of an embodiment of an example DRAM device 2100 that can include an architecture in which component devices in the periphery to the memory array of DRAM device 2100 are structured in semiconductor on insulator, as taught herein. DRAM device 2100 can include an array of memory cells 2125 (only one being labeled in FIG. 21 for ease of presentation) arranged in rows 2154-1, 2154-2, 2154-3, and 2154-4 and columns 2156-1, 2156-2, 2156-3, and 2156-4. For simplicity and ease of discussion, the array is shown in only two dimensions, but the array can be extended into the third dimension. Further, while only four rows 2154-1, 2154-2, 2154-3, and 2154-4 and four columns 2156-1, 2156-2, 2156-3, and 2156-4 of four memory cells are illustrated, DRAM devices like DRAM device 2100 can have significantly more memory cells 2125 (e.g., tens, hundreds, or thousands of memory cells) per row or per column.

Each memory cell 2125 can include a single transistor 2127 and a single capacitor 2129, which is commonly referred to as a 1T1C (one-transistor—one capacitor cell). One plate of capacitor 2129, which can be termed the “node plate,” is connected to the drain terminal of transistor 2127, whereas the other plate of the capacitor 2129 is connected to a reference 2124, which can be ground. Each capacitor 2129 within the array of 1T1C memory cells 2125 typically serves to store one bit of data, and the respective transistor 2127 serves as an access device to write to or read from storage capacitor 2129.

The transistor gate terminals within each row of rows 2154-1, 2154-2, 2154-3, and 2154-4 are portions of respective WLs 2130-1, 2130-2, 2130-3, and 2130-4 (for example, word lines), and the transistor source terminals within each of columns 2156-1, 2156-2, 2156-3, and 2156-4 are electrically connected to respective DLs 2110-1, 2110-2, 2110-3, and 2110-4 (for example bit lines). A row decoder 2132 can selectively drive the individual WLs 2130-1, 2130-2, 2130-3, and 2130-4, responsive to row address signals 2131 input to row decoder 2132. Transistors within row decoder 2132 can be structured having components in semiconductor on insulator. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 2140, which can transfer bit values between the memory cells 2125 of the selected row of the rows 2154-1, 2154-2, 2154-3, and 2154-4 and input/output buffers 2146 (for write/read operations) or external input/output data buses 2148. Transistors within sense amplifier circuitry 2140 can be structured having components in semiconductor on insulator.

A column decoder 2142 responsive to column address signals 2141 can select which of the memory cells 2125 within the selected row is read out or written to. Transistors within column decoder 2142 can be structured having components in semiconductor on insulator. Alternatively, for read operations, the storage capacitors 2129 within the selected row may be read out simultaneously and latched, and the column decoder 2142 can then select which latch bits to connect to the output data bus 2148. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 2100 may be implemented as an integrated circuit within a package that includes pins for receiving supply voltages (e.g., to provide the source and gate voltages for the transistors 2127) and signals (including data, address, and control signals). FIG. 21 depicts DRAM device 2100 in simplified form to illustrate basic structural components, omitting many details of the memory cells 2125 and associated WLs 2130-1, 2130-2, 2130-3, and 2130-4 and DLs 2110-1, 2110-2, 2110-3, and 2110-4 as well as the peripheral circuitry. For example, in addition to the row decoder 2132 and column decoder 2142, sense amplifier circuitry 2140, and buffers 2146, DRAM device 2100 may include further peripheral circuitry, such as a memory control unit that controls the memory operations based on control signals (provided, e.g., by an external processor), additional input/output circuitry, etc. Transistors within the peripheral circuitry can be structured having components in semiconductor on insulator. Details of such peripheral circuitry are generally known to those of ordinary skill in the art and not further discussed herein.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

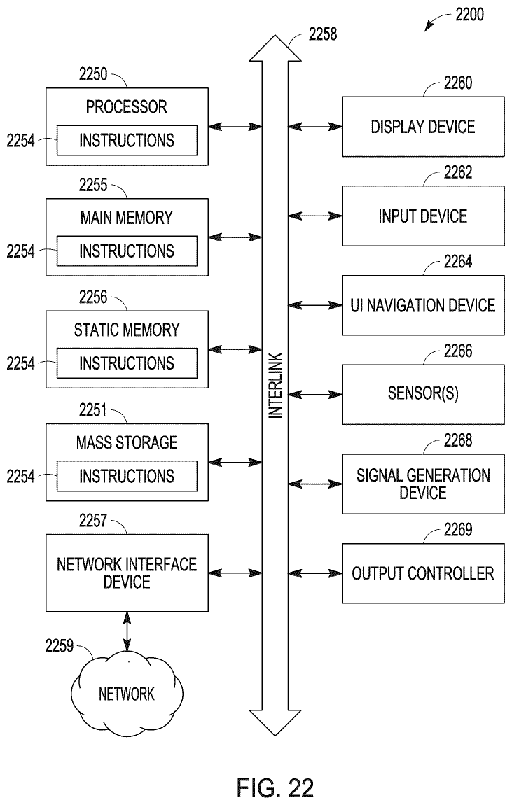

FIG. 22 illustrates a block diagram of an example machine 2200 having one or more embodiments of memory components discussed herein. In alternative embodiments, machine 2200 may operate as a standalone device or may be connected (e.g., networked) to other machines. In a networked deployment, machine 2200 may operate in the capacity of a server machine, a client machine, or both in server-client network environments. In an example, machine 2200 may act as a peer machine in peer-to-peer (P2P) (or other distributed) network environment. Machine 2200 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 2200 can include one or more memory devices having structures as discussed with respect to structure 200 of FIG. 2, structure 800 of FIG. 8, structure 1400 of FIG. 14, structure 1600 of FIG. 16, structure 1700 of FIG. 17, structure 1800 of FIG. 18, or other similar structure as taught herein.

Machine (e.g., computer system) 2200 may include a hardware processor 2250 (e.g., a CPU, a GPU, a hardware processor core, or any combination thereof), a main memory 2255 and a static memory 2256, some or all of which may communicate with each other via an interlink (e.g., bus) 2258. Machine 2200 may further include a display device 2260, an alphanumeric input device 2262 (e.g., a keyboard), and a user interface (UI) navigation device 2264 (e.g., a mouse). In an example, display device 2260, alphanumeric input device 2262, and UI navigation device 2264 may be a touch screen display. Machine 2200 may additionally include a mass storage (e.g., drive unit) 2251, a signal generation device 2268 (e.g., a speaker), a network interface device 2257, and one or more sensors 2266, such as a global positioning system (GPS) sensor, compass, accelerometer, or other sensor. Machine 2200 may include an output controller 2269, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 2200 may include a machine-readable medium on which is stored one or more sets of data structures or instructions 2254 (for example, software or microcode) embodying or utilized by machine 2200. Instructions 2254 may also reside, completely or at least partially, within main memory 2255, within static memory 2256, within mass storage 2251, or within hardware processor 2250 during execution thereof by machine 2200. In an example, one or any combination of hardware processor 2250, main memory 2255, static memory 2256, or mass storage 2251 may constitute machine-readable medium. Machine-readable medium can be a single medium or multiple media (e.g., a centralized or distributed database, or associated caches and servers) configured to store one or more instructions 2254.

The term “machine-readable medium” may include any medium that is capable of storing instructions for execution by machine 2200 and that cause machine 2200 to perform any one or more of the techniques for which machine 2200 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 2254 (e.g., software, programs, microcode, an operating system (OS), etc.) or other data stored on mass storage 2251, can be accessed by main memory 2255 for use by processor 2250. Main memory 2255 (e.g., DRAM) is typically fast, but volatile, and thus a different type of storage than mass storage 2251 (e.g., an SSD), which is suitable for long-term storage, including while in an “off” condition. Instructions 2254 or data in use by a user or machine 2200 are typically loaded in main memory 2255 for use by processor 2250. When main memory 2255 is full, virtual space from mass storage 2251 can be allocated to supplement main memory 2255; however, because mass storage 2251 is typically slower than main memory 2255, and write speeds are typically at least twice as slow as read speeds, use of virtual memory can greatly reduce user experience due to storage device latency (in contrast to main memory 2255, e.g., DRAM). Further, use of mass storage 2251 for virtual memory can greatly reduce the usable lifespan of mass storage 2251.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 2254 may further be transmitted or received over a network 2259 using a transmission medium via network interface device 2257 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 2257 may include one or more physical jacks (e.g., Ethernet, coaxial, or phone jacks) or one or more antennas to connect to the communications network 2226. In an example, network interface device 2257 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 2200 or data to or from machine 2200. The transportation can include using digital or analog communications signals that can be transmitted over the transmission medium to facilitate communication of such software or data.

The following are example embodiments of devices and methods, in accordance with the teachings herein.

An example memory device 1 can comprise a memory array region and a periphery to the memory array region. The periphery can include devices structured with components in semiconductor on insulator regions in the periphery, where the semiconductor on insulator regions is disposed on a bulk substrate.

An example memory device 2 can include features of example memory device 1 and can include the semiconductor on insulator regions being contained entirely in the periphery.

An example memory device 3 can include features of any of the preceding example memory devices and can include the semiconductor on insulator regions being located above a bottom level of shallow trench insulators that separate the devices from each other in the periphery.

An example memory device 4 can include features of any of the preceding example memory devices and can include a high-voltage device in the periphery. The high-voltage device can be structured in the bulk substrate without a component in a semiconductor on insulator region in the periphery.

An example memory device 5 can include features of any of the preceding example memory devices and can include a high-voltage device in the periphery, where the high-voltage device is structured with components in one of the semiconductor on insulator regions and with drift regions on a top surface of the semiconductor on insulator region.

An example memory device 6 can include features of any of the preceding example memory devices and can include a high-voltage device in the periphery. The high-voltage device can be structured with components in one of the semiconductor on insulator regions, with the one semiconductor on insulator region on a ground-plane on a p-type well and on another ground plane on a n-type well.

An example memory device 7 can include features of example memory device 6 and any of the preceding example memory devices and can include the high-voltage device to include drift regions on a top surface of the semiconductor on insulator region.

An example memory device 8 can include features of any of the preceding example memory devices and can include the devices structured with components in semiconductor on insulator regions in the periphery to include a device being part a periphery circuit or a pitch circuit.

In an example memory device 9, any of the memory devices of example memory devices 1 to 8 may include memory devices incorporated into an electronic apparatus further comprising a host processor or memory controller and a communication bus extending between the host processor/memory controller and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below example methods 1 to 11 and methods 12 to 20.

An example method 1 of forming a memory device can comprise forming a memory array region and forming devices in a periphery to the memory array region. The devices can be structured with components in silicon on insulator regions in the periphery, where the silicon on insulator regions are disposed on a bulk substrate.

An example method 2 of forming a memory device can include features of example method 1 of forming a memory device and can include forming the silicon on insulator regions entirely contained in the periphery.

An example method 3 of forming a memory device can include features of any of the preceding example methods of forming a memory device and can include forming the silicon on insulator regions and shallow trench insulators such that the silicon on insulator regions are at a level between a top surface of the bulk substrate and a bottom level of the shallow trench insulators, the shallow trench insulators to separate the devices from each other in the periphery.

An example method 4 of forming a memory device can include features of any of the preceding example methods of forming a memory device and can include maintaining a region in the periphery without having a silicon on insulator region, while forming the silicon on insulator regions in the periphery in which components of the devices are to be formed; and forming a high-voltage device in the bulk substrate in the region in the periphery without having a silicon on insulator region.

An example method 5 of forming a memory device can include features of any of the preceding example methods of forming a memory device and can include forming a high-voltage device in the periphery with the high-voltage device structured with components in one silicon on insulator region of the silicon on insulator regions, including depositing an epitaxial layer on a top surface of the one silicon on insulator region and forming drift regions in the epitaxial layer.

An example method 6 of forming a memory device can include features of any of the preceding example methods of forming a memory device and can include forming a silicon on insulator region of the silicon on insulator regions in the periphery on a ground-plane on a p-type well and on another ground plane on a n-type well; and forming a high-voltage device on the silicon on insulator that is on the ground-plane on the p-type well and on the other ground plane on the n-type well.

An example method 7 of forming a memory device can include features of example method 6 of forming a memory device and any of the preceding example methods of forming a memory device and can include depositing an epitaxial layer on a top surface of the silicon on insulator region; and forming drift regions in the epitaxial layer.

In an example method 8, any of the example methods 1 to 7 of forming a memory device may be performed in forming an electronic apparatus further comprising a host processor and a communication bus extending between the host processor and a memory system.

In an example method 9 of forming a memory device, any of the example methods 1 to 8 of forming a memory device may be modified to include operations set forth in any other of example methods 1 to 8.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include performing functions associated with any features of example memory devices 1 to 12.

An example method 12 of forming a memory device can comprise forming a silicon germanium region on a silicon substrate; forming a silicon region on and contacting the silicon germanium region; removing the silicon germanium region, forming a cavity between the silicon region and the silicon substrate; forming an oxide in the cavity, generating silicon on insulator regions in a periphery to a memory array region in the silicon substrate; and forming devices in the periphery, including structuring components of the devices in the silicon on insulator regions.

An example method 13 of forming a memory device can include features of example method 12 of forming a memory device and can include before forming the silicon germanium region and the silicon region, removing a silicon region of the silicon substrate in the periphery to the memory array region of the silicon substrate, forming a removed region of the silicon substrate, without removing silicon material from the silicon substrate in the memory array region; forming the silicon germanium region and silicon region on the silicon germanium region on the silicon substrate in the removed region; forming shallow trench insulators in the silicon region on the silicon germanium region and in the silicon germanium region; removing the silicon germanium region and forming the oxide with respect to the shallow trench insulators to generate the silicon on insulator regions; and forming the devices having components of the devices in the silicon on insulator regions, separated by the shallow trench insulators.

An example method 14 of forming a memory device can include features of example method 13 of forming a memory device and any of the preceding example method 12 of forming a memory device and can include forming memory cells in the memory array region after generating the silicon on insulator regions.

An example method 15 of forming a memory device can include features of any of the preceding example methods 12-14 of forming a memory device and can include forming the silicon germanium region on the silicon substrate in the periphery to the memory array region and in the memory array region; forming the silicon region on and contacting the silicon germanium region in the periphery to the memory array region and in the memory array region; removing the silicon region on and contacting the silicon germanium region and the silicon germanium region in the memory array region; forming shallow trench insulators in the silicon region on the silicon germanium region and in the silicon germanium region; removing the silicon germanium region and forming the oxide with respect to the shallow trench insulators to generate the silicon on insulator regions; and forming the devices having components of the devices in the silicon on insulator regions, separated by the shallow trench insulators.

An example method 16 of forming a memory device can include features of example method 15 of forming a memory device and any of the preceding example methods 12 to 15 of forming a memory device and can include forming devices to include forming the devices in a periphery circuit or a pitch circuit.

In an example method 17 of forming a memory device, any of the example methods 12 to 16 of forming a memory device may be performed in forming an electronic apparatus further comprising a host processor and a communication bus extending between the host processor and a memory system.

In an example method 18 of forming a memory device, any of the example methods 12 to 17 of forming a memory device may be modified to include operations set forth in any other of example methods 12 to 17 of forming a memory device.

In an example method 19 of forming a memory device, any of the example methods 12 to 18 of forming a memory device may be implemented at least in part through use of instructions stored as a physical state in one or more machine-readable storage devices.

An example method 20 of forming a memory device can include features of any of the preceding example methods 12 to 19 of forming a memory device and can include performing functions associated with any features of example memory devices 1 to 12.

An example machine-readable storage device storing instructions, that when executed by one or more processors, cause a machine to perform operations, can comprise instructions to perform functions associated with any features of example memory devices 1 to 12 or perform form methods associated with any features of example methods 1 to 11 of forming a memory device or example methods 12 to 20 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a memory array region; and
a periphery to the memory array region, the periphery including devices structured with components in semiconductor on insulator regions in the periphery, the semiconductor on insulator regions disposed on a bulk substrate.

2. The memory device of claim 1, wherein the semiconductor on insulator regions are contained entirely in the periphery.

3. The memory device of claim 1, wherein the semiconductor on insulator regions are located above a bottom level of shallow trench insulators that separate the devices from each other in the periphery.

4. The memory device of claim 1, wherein the memory device includes a high-voltage device in the periphery, the high-voltage device structured in the bulk substrate without a component in a semiconductor on insulator region in the periphery.

5. The memory device of claim 1, wherein the memory device includes a high-voltage device in the periphery, the high-voltage device structured with components in one of the semiconductor on insulator regions and with drift regions on a top surface of the semiconductor on insulator region.

6. The memory device of claim 1, wherein the memory device includes a high-voltage device in the periphery, the high-voltage device structured with components in one of the semiconductor on insulator regions, with the one semiconductor on insulator region on a ground-plane on a p-type well and on another ground plane on a n-type well.

7. The memory device of claim 6, wherein the high-voltage device includes drift regions on a top surface of the semiconductor on insulator region.

8. The memory device of claim 1, wherein the devices structured with components in semiconductor on insulator regions in the periphery includes a device being part a periphery circuit or a pitch circuit.

9. A method of forming a memory device, the method including:
forming a memory array region; and
forming devices, in a periphery to the memory array region, structured with components in silicon on insulator regions in the periphery, the silicon on insulator regions disposed on a bulk substrate.

10. The method of claim 9, wherein the method includes forming the silicon on insulator regions entirely contained in the periphery.

11. The method of claim 9, wherein the method includes forming the silicon on insulator regions and shallow trench insulators such that the silicon on insulator regions are at a level between a top surface of the bulk substrate and a bottom level of the shallow trench insulators, the shallow trench insulators to separate the devices from each other in the periphery.

12. The method of claim 9, wherein the method includes:
maintaining a region in the periphery without having a silicon on insulator region, while forming the silicon on insulator regions in the periphery in which components of the devices are to be formed; and
forming a high-voltage device in the bulk substrate in the region in the periphery without having a silicon on insulator region.

13. The method of claim 9, wherein the method includes forming a high-voltage device in the periphery with the high-voltage device structured with components in one silicon on insulator region of the silicon on insulator regions, including depositing an epitaxial layer on a top surface of the one silicon on insulator region and forming drift regions in the epitaxial layer.

14. The method of claim 9, wherein the method includes:
forming a silicon on insulator region of the silicon on insulator regions in the periphery on a ground-plane on a p-type well and on another ground plane on a n-type well; and
forming a high-voltage device on the silicon on insulator that is on the ground-plane on the p-type well and on the other ground plane on the n-type well.

15. The method of claim 14, wherein the method includes
depositing an epitaxial layer on a top surface of the silicon on insulator region; and
forming drift regions in the epitaxial layer.

16. A method of forming a memory device, the method comprising:
forming a silicon germanium region on a silicon substrate;
forming a silicon region on and contacting the silicon germanium region;
removing the silicon germanium region, forming a cavity between the silicon region and the silicon substrate;
forming an oxide in the cavity, generating silicon on insulator regions in a periphery to a memory array region in the silicon substrate; and
forming devices in the periphery, including structuring components of the devices in the silicon on insulator regions.

17. The method of claim 16, wherein the method includes:
before forming the silicon germanium region and the silicon region, removing a silicon region of the silicon substrate in the periphery to the memory array region of the silicon substrate, forming a removed region of the silicon substrate, without removing silicon material from the silicon substrate in the memory array region;
forming the silicon germanium region and silicon region on the silicon germanium region on the silicon substrate in the removed region;
forming shallow trench insulators in the silicon region on the silicon germanium region and in the silicon germanium region;
removing the silicon germanium region and forming the oxide with respect to the shallow trench insulators to generate the silicon on insulator regions; and
forming the devices having components of the devices in the silicon on insulator regions, separated by the shallow trench insulators.

18. The method of claim 17, wherein the method includes forming memory cells in the memory array region after generating the silicon on insulator regions.

19. The method of claim 16, wherein the method includes:
forming the silicon germanium region on the silicon substrate in the periphery to the memory array region and in the memory array region;
forming the silicon region on and contacting the silicon germanium region in the periphery to the memory array region and in the memory array region;
removing the silicon region on and contacting the silicon germanium region and the silicon germanium region in the memory array region;
forming shallow trench insulators in the silicon region on the silicon germanium region and in the silicon germanium region;
removing the silicon germanium region and forming the oxide with respect to the shallow trench insulators to generate the silicon on insulator regions; and
forming the devices having components of the devices in the silicon on insulator regions, separated by the shallow trench insulators.

20. The method of claim 16, wherein forming devices includes forming the devices in a periphery circuit or a pitch circuit.
